(19) United States
(12) Patent Application Publication
(10) Pub. No.: US 2012/0175699 A1
(43) Pub. Date: Jul. 12, 2012

(54) TRENCH MOSFET WITH SUPER PINCH-OFF REGIONS AND SELF-ALIGNED TRENCHED CONTACT

(75) Inventor: Fu-Yuan HSIEH, Banciao City (TW)

(73) Assignee: FORCE MOS TECHNOLOGY CO., LTD., Banciao City (TW)

(21) Appl. No.: 12/985,363

(22) Filed: Jan. 6, 2011

(51) Int. Cl. H01L 27/088; H01L 21/8234

(52) U.S. Cl. 257/332; 438/237; 257/E27.06; 257/E21.63

(57) ABSTRACT

A power semiconductor device having a self-aligned structure and super pinch-off regions is disclosed. The on-resistance is reduced by forming a short channel without having punch-through issue. The on-resistance is further reduced by forming an on-resistance reduction implanted drift region between adjacent shield electrodes, having doping concentration heavier than epitaxial layer without degrading breakdown voltage with a thick oxide on bottom and sidewalls of the shield electrode. Furthermore, the present invention enhance the switching speed comparing to the prior art.

### FIELD OF THE INVENTION

This invention relates generally to the cell structure, device configuration and fabricating method of semiconductor devices. More particularly, this invention relates to configuration and fabricating method of an improved trench MOSFET (Metal Oxide Semiconductor Field Effect Transistor) with super pinch-off regions and self-aligned trenched source-body contact.

### BACKGROUND OF THE INVENTION

For power MOSFETs, which are well known in the semiconductor industry, reducing the cell pitch is one of the most challenging technologies to those skilled in the art. A cross-sectional view of such an N-channel trench MOSFET disclosed in U.S. Pat. No. 7,595,524 is shown in FIG. 1. MOSFET 100 has a plurality of gate trenches 101 extending into an N epitaxial layer 102 supported onto an N+ substrate 103. Each gate trench 103 has upper sidewalls that fan out and contains: (a) a poly-silicon layer 104 as gate electrode; (b) a dielectric region 105 over the poly-silicon layer 104; (c) a gate oxide layer padded by the poly-silicon layer 104. Contact openings 106 extend into the N epitaxial layer 102 between adjacent gate trenches 101 such that each gate trench 101 and an adjacent contact opening 106 form a common upper sidewall portion. P body regions 107 extend between adjacent gate trenches 101. N+ source regions 108 are formed near top surface of the P body regions 107 and disposed below a corresponding one of the common upper sidewalls. A single metal layer 109 is deposited over the dielectric region 105 and further extending into the contact openings 106. A P+ ohmic body contact region 110 is formed underneath each contact opening 106 to reduce the contact resistance between the P body region 107 and the single metal layer 109.

The prior art illustrated in FIG. 1 has obvious advantages of self-aligned trenched source-body contact to the gate trenches 101 due to formation of the contact openings 106 is implemented by formation of the gate trenches portion that fan out. However, there are still some disadvantages constraining the shrinkage of the cell pitch. As mentioned above, the single metal layer 109 is directly deposited over the dielectric region 105 and into the contact openings 106 to contact the P body regions 107 and the N+ source regions 108, this will result in difficulty for the cell pitch shrinkage for the trenched source-body contact especially when size of the contact openings 106 is below 1.0 um because of poor metal step coverage. Furthermore, as less mesa width (width of mesa between adjacent gate trenches 101) has less Idsx (the leakage current between drain and source), the Idsx can not be further reduced because the mesa is hard to be shrunk and pinch effect of the electric field in the mesa is so strongly related to the mesa width.

Besides, the contact openings 106 are formed extending into the P body regions 107 that extending between adjacent gate trenches 101, and the P+ ohmic body contact region 110 within the P body region 107 below the contact opening 106 forms a parasitic diode (as illustrated in FIG. 2) between the source and the drain with slow switch speed.

Moreover, Qgd (charge between gate and drain) is still high in the N-channel trench MOSFET in FIG. 1 because trench gate bottom has large overlap area interfacing with the epitaxial layer, resulting in high gate charge Qgd.

Accordingly, it would be desirable to provide a new and improved configuration and fabricating method for a trench MOSFET with reduced cell pitch and better performance without complicating the process technology.

### SUMMARY OF THE INVENTION

It is therefore an object of the present invention to provide a new and improved semiconductor power device such as a trench MOSFET with two type gate trenches for device shrinkage by forming self-aligned contact and super pinch-off regions for reduced on-resistance by forming short channel. Briefly, in a preferred embodiment, this invention discloses a power semiconductor device comprising: a plurality of first type gate trenches extending into a silicon layer of a first conductivity type; a plurality of second type gate trenches extending into the silicon layer and formed symmetrically and disposed below the first type gate trenches, each second type gate trench having narrower trench width than the first type gate trench, and each second type gate trench surrounded by source regions of the first conductivity type and body regions of a second conductivity type adjacent opposing sidewalls of each second type gate trench in upper portion of the silicon layer; a gate electrode filled in the second type gate trenches; a dielectric layer filled in the first type gate trenches symmetrically over the gate electrode; a gate insulating layer insulating the gate electrode from adjacent body regions, source regions and silicon layer; a plurality of source-body contact trenches formed between two adjacent of the first type gate trenches and penetrating through the source regions and the body regions and extending into the silicon layer between two adjacent of the second type gate trenches; and an anti-punch through region of said second conductivity type surrounding sidewall and bottom of each source-body contact trench below the source region.

In order to further reduce Qgd, a shield electrode is disposed in lower portion of gate trenches in some embodiments connecting to a source metal. Briefly, in another preferred embodiment, this invention discloses a power semiconductor device comprising: a plurality of first type gate trenches extending into a silicon layer of a first conductivity type; a plurality of second type gate trenches extending into the silicon layer and formed symmetrically disposed below the first type gate trenches, each second type gate trench having narrower trench width than the first type gate trench, and each second type gate trench surrounded by source regions of the first conductivity type and body regions of a second conductivity type adjacent opposing sidewalls of each second type gate trench in upper portion of the silicon layer; a gate electrode and a shield electrode disposed in the second type gate trench, wherein the gate electrode and the shield electrode insulated from each other by an inter-electrode insulation layer and from adjacent body regions, source regions and silicon layer by gate insulating layers, wherein the source regions and the body regions being adjacent to the gate electrode; the gate electrode connected to a gate metal and shield electrode to a source metal; a dielectric layer filled in the first type gate trenches symmetrically over the gate electrode; a plurality of source-body contact trenches formed between two adjacent of the first type gate trenches and penetrating through the source regions and the body regions and extending into the silicon layer between two adjacent of the second type gate trenches; and an anti-through punch-through region of the second conductivity type surrounding sidewall and bottom of each source-body contact trench below the source region.

In other preferred embodiments, this invention can be implemented including one or more of following features: each second type gate trench symmetrically disposed below each first type gate trench; the gate electrode is doped poly-silicon layer; the power semiconductor device further comprises a tungsten layer padded by a barrier layer filled into each source-body contact trench for contacting the source regions and the body regions along sidewalls of the source-body contact trenches, the tungsten layer electrically connected to a source metal; the tungsten layer in FIG. 8 is only filled within each source-body contact trench but not extended over on top surface of the dielectric layer filled in first type gate trenches; the tungsten layer in some embodiment is not only filled within each source-body contact trench but also further extended over top surface of the dielectric layer filled in first type gate trenches; the power semiconductor device further comprises a source metal over the silicon layer and the tungsten layer, wherein the source metal electrically connected to the tungsten layer; the power semiconductor device further comprises an on-resistance reduction implanted region of the first conductivity type extending between two adjacent of the second type gate trenches below the body regions for further Rds reduction, the on-resistance reduction region having higher doping concentration than the silicon layer; the power semiconductor device further comprises at least one implanted pinch-off island of the second conductivity type in the silicon layer underneath the anti-punch through region and between two adjacent of the gate electrodes for further Idsx reduction; the source metal is Al alloys or Cu layer; the source metal is Ni/Ag or Ni/Au layer; the source metal is composed of a Ni/Au or Ni/Ag over a Al alloys layer; the power semiconductor device further comprises a resistance reduction layer such as Ti or Ti/TiN layer underneath the source metal; the source-body contact trenches are self-aligned to the first type gate trenches; the silicon layer is an epitaxial layer of the first conductivity type supported onto a substrate of the first conductivity type, wherein the epitaxial layer having lower doping concentration than the substrate; the gate electrode and shield electrode are doped poly-silicon layers, and the shield electrode has lower doping concentration than the gate electrode; the power semiconductor device further comprises a parasitic resistor disposed between the shield electrode and the source metal, the parasitic resistor has a resistance from 0.5 ohms to 200 ohms adjusted by sheet resistance of the shield electrode; the power semiconductor device further comprises at least one implanted pinch-off island of the second conductivity type in the silicon layer underneath the anti-punch through region and between two adjacent of the shield electrodes for further Idsx reduction; the gate insulating layers comprises a thicker oxide layer on bottom and sidewalls of the shield electrodes and a thinner oxide layer on sidewalls of the gate electrodes.

This invention further disclosed a method of manufacturing a power semiconductor device with two type gate trenches for device shrinkage by forming self-aligned contact and super pinch-off regions for reduced on-resistance by forming a short channel comprising the steps of: forming a plurality of first type gate trenches extending into a silicon layer; then forming a plurality of second type gate trenches in the silicon layer and symmetrically disposed below the first type gate trenches, wherein the second type gate trenches having narrower trench width than the first type gate trenches; forming body regions having opposite conductivity type to the silicon layer between two adjacent of the first type gate trenches and in upper portion of the silicon layer between two adjacent of the second type gate trenches; forming a dielectric layer within the first type gate trenches; removing portion of the body regions from spaces between two adjacent of the first type gate trenches; then forming source regions having opposite conductivity type to the body regions in upper portion of the body regions; forming a plurality of source-body contact trenches along sidewalls of the first type gate trenches and penetrating through the source regions and the body regions and extending into the silicon layer between two adjacent of the second type gate trenches, wherein the source-body contact trenches are self-aligned to the first type gate trenches; forming an anti-punch through region surrounding bottom and sidewall of each source-body contact trench below the source region.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional view of a trench MOSFET of prior art.

FIG. 2 is an equal circle of the trench MOSFET shown in FIG. 1

FIG. 3A is a cross-sectional view of a preferred embodiment according to the present invention.

FIG. 3B is an equal circle of the trench MOSFET shown in FIG. 3A.

FIG. 4 is a profile showing relationship between mesa width and Idsx.

FIG. 5 is a cross-sectional view of another preferred embodiment according to the present invention.

FIG. 6 is a cross-sectional view of another preferred embodiment according to the present invention.

FIG. 7 is a cross-sectional view of another preferred embodiment according to the present invention.

FIG. 8 is a cross-sectional view of another preferred embodiment according to the present invention.

FIG. 9 is a cross-sectional view of another preferred embodiment according to the present invention.

FIGS. 10A˜10K are a serial of side cross-sectional views for showing the processing steps for fabricating the trench MOSFET as shown in FIG. 3A.

FIG. 11 is a cross-sectional view for showing one of the processing steps for fabricating the trench MOSFET as shown in FIG. 5

FIGS. 12A˜12D are a serial of side cross-sectional views for showing the processing steps for fabricating the trench MOSFET as shown in FIG. 6.

FIG. 13 is a cross-sectional view for showing one of the processing steps for fabricating the trench MOSFET as shown in FIG. 9

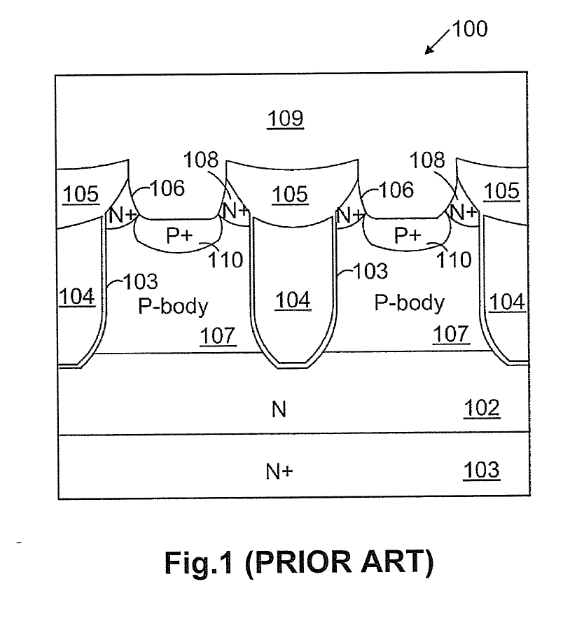

### DETAILED DESCRIPTION OF THE EMBODIMENTS

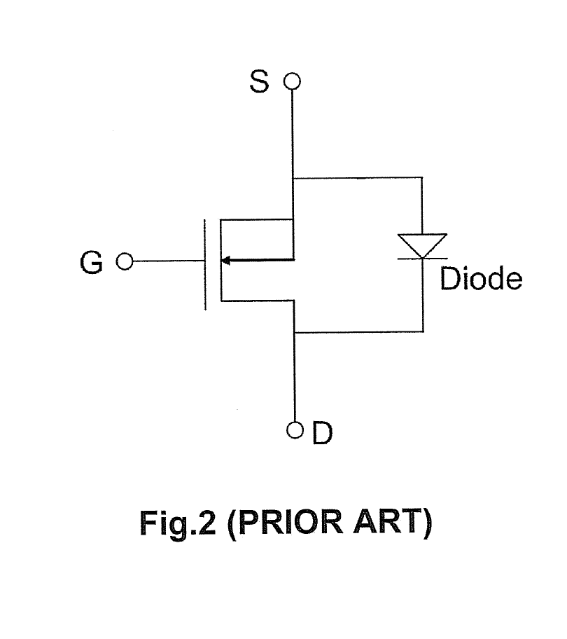

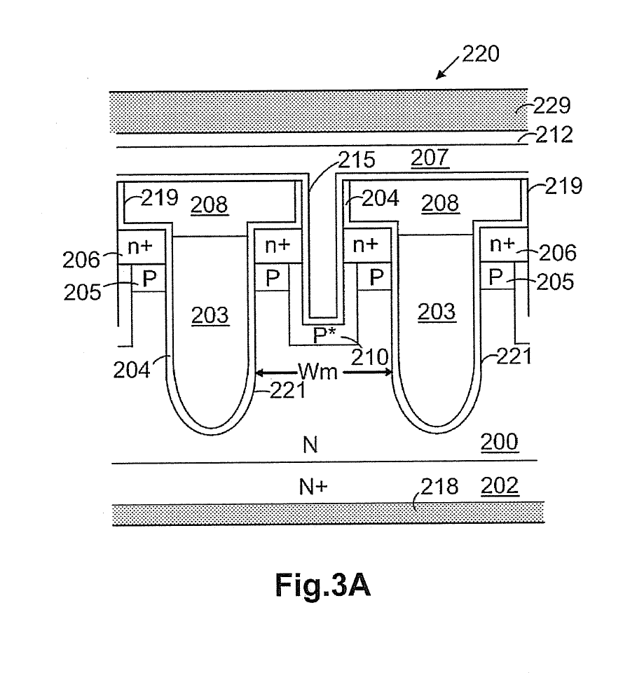

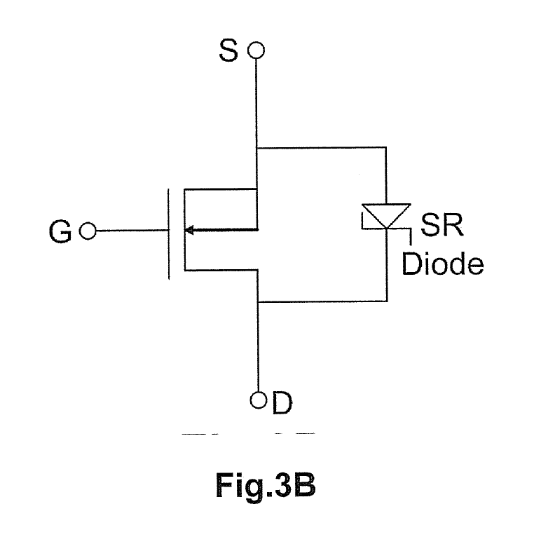

Please refer to FIG. 3A for a preferred N-channel trench MOSFET 220 with two type gate trenches for device shrinkage by forming self-aligned contact and super pinch-off regions for reduced on-resistance by forming a short channel according to the present invention. The N-channel trench MOSFET 220 is formed in an N epitaxial layer 200 supported on a heavily doped N+ substrate 202 which coated with back metal 218 on the rear side as drain. A plurality of first type gate trenches 219 are formed extending from the top surface of the N epitaxial 200, and a plurality of second type gate trenches 221 are formed symmetrically disposed below the first type gate trenches 219 and extending into the N epitaxial layer 200, wherein the second type gate trenches 221 have narrower trench width than the first type gate trenches 219. A single gate insulating layer 204, which can be implemented by gate oxide layer, is padded along inner surface of the first type gate trenches 219 and the second type gate trenches 221. Within the second type gate trenches 221, n+ or p+ doped poly-silicon layer is filled onto the gate insulating layer 204 to act as gate electrode 203, while within the first type gate trenches 219, dielectric regions 208 are filled over the gate electrode 203 and close to the gate insulating layer 204. P body regions 205 are formed adjacent to opposing sidewalls of the second type gate trenches 221 and in upper portion of the N epitaxial layer 200 below the first type gate trenches 219 while n+ source regions 206 formed near top surface of the P body regions 205 and surrounding opposing sidewalls of the second type gate trenches 221. The gate insulating layer 204 insulates the gate electrode 203 from the n+ source regions 206, the P body regions 205 and the N epitaxial layer 200. Between every two adjacent first type gate trenches 219, a source-body contact trench 215 is formed self-aligned to the first type gate trenches 219. The source-body contact trench 215 further penetrates through the n+ source regions 206 and the P body regions 205 and extends into the N epitaxial layer 200 between every two adjacent first type gate trenches 221. A tungsten metal 207 padded by a barrier layer of Ti/TiN or Ta/TiN or Co/TiN is formed not only filled into the source-body contact trench 215 but also extended over the N epitaxial layer 200. A P* anti-punch through region 210 is surrounding bottom and sidewall of each source-body contact trench 215 below the n+ source regions 206. Onto the tungsten metal 207, a source metal 222 padded by a resistance-reduction layer is formed contacting the n+ source regions 206 and the P body regions 205 via the tungsten metal 207 for better metal step coverage. According to this invention, the super pinch-off regions includes two type pinch-off regions: a 1^{st} pinch-off region is generated by the lower portion of two adjacent of the second type gate trenches and below the P*/N-epitaxial junction on bottom of the source-body contact trench 215; and a 2^{nd} pinch-off region is generated by the upper portion of one second type gate trench and the P*/N-epitaxial junction along the sidewall of the source-body contact trench 215 below the P-body/N-epitaxial junction. Meanwhile, a soft recovery diode (SR diode, as show in FIG. 3B) is formed between the source and the drain instead of the diode in FIG. 2, therefore improving switching speed of the trench MOSFET 220. On the other hand, the anti-PT P* region 210 also acts as P body contact resistance reduction region for forming ohmic contact between the tungsten metal 207 and the P body region 205. The N-channel trench MOSFET 220 further comprises a source metal 229 padded by a resistance-reduction layer 212 of Ti or TiN onto the contact interlayer to contact with the tungsten plug 207, wherein the source metal 229 can be implemented by Al alloys or Cu layer or Ni/Ag or Ni/Au or composing of a Ni/Au or Ni/Ag over a Al alloys layer.

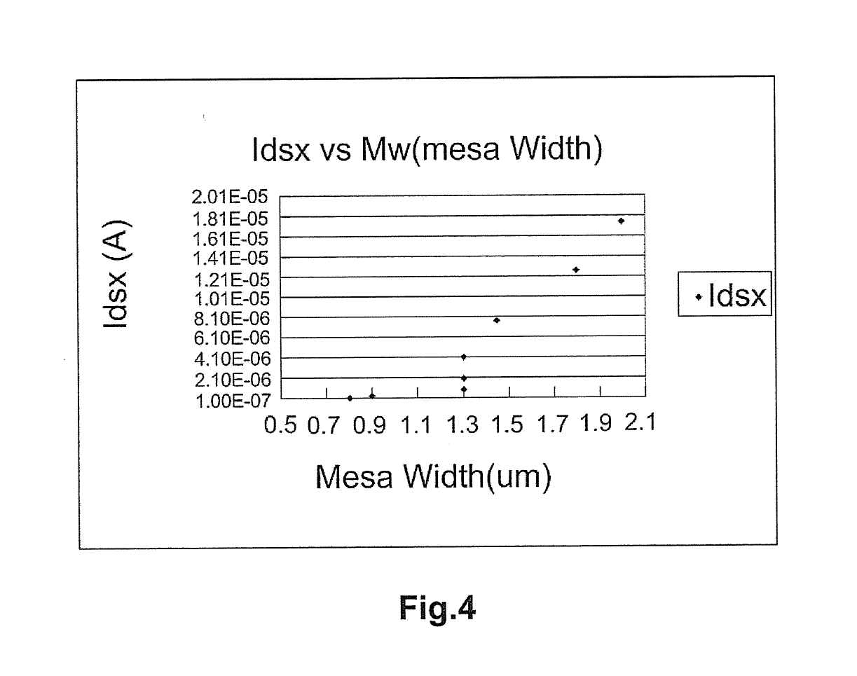

Please refer to FIG. 4 for relationship between the mesa width and Idsx of the device with a short channel length less than 0.5 um, from which it can be seen that, Idsx is dramatically decreased when the wide mesa width Wₘ (as shown in FIG. 3A) less than 1.3 um. The inventive device having source-body contact trench and super pinch-off regions effectively solves difficulty in shrinkage of mesa width happens in the prior art when size of source-body contact trench below 1.0 um.

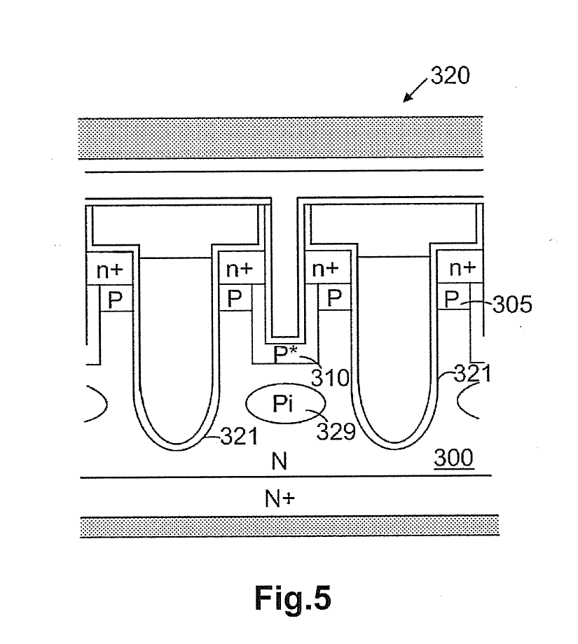

Please refer to FIG. 5 for another preferred N-channel trench MOSFET 320 with two type gate trenches for device shrinkage by forming self-aligned contact and super pinch-off regions for reduced on-resistance by forming a short channel according to the present invention, which has similar configuration to FIG. 3A except that, there is an additional single implanted P type pinch-off island Pi 329 in N epitaxial layer 300 underneath anti-PT P* region 310 and between two adjacent second type gate trenches 321 to form a third type pinch-off region between the second type gate trenches 321 and the single implanted P type pinch-off island Pi 329 for further Idsx reduction.

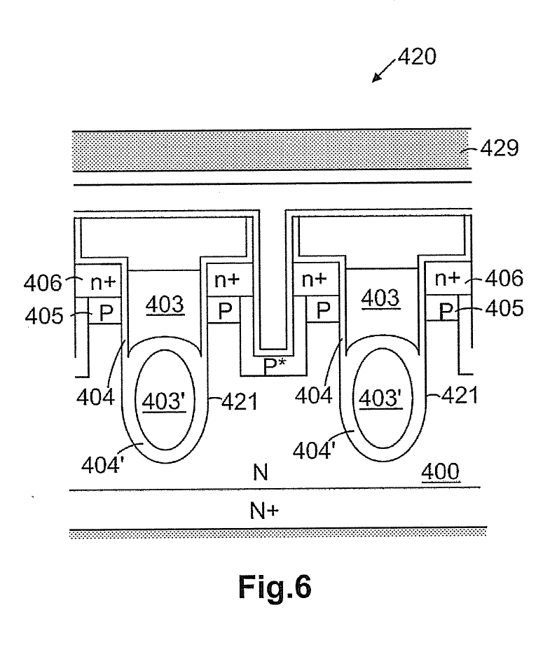

Please refer to FIG. 6 for another preferred N-channel trench MOSFET 420 with two type gate trenches for device shrinkage by forming self-aligned contact and super pinch-off regions for reduced on-resistance by forming short channel according to the present invention, which has similar configuration to FIG. 3A except that, second type gate trenches 421 include: gate electrodes 403 in upper portion and shield electrodes 403′ in lower portion, wherein the shield electrodes 403′ are connected to source metal 429 through a parasitic resistance (not shown) disposed in the second gate trenches 421 with a resistance ranging from 0.5 ohms to 200 ohms and insulated from the gate electrodes 403 by an inter-electrode insulation layer which is grown on top surface of said shield electrode during formation of a first gate insulating layer 404. The shield electrodes 403′ are insulated from adjacent N epitaxial layer 400 by a second gate insulating layer 404′ which is thicker than the first gate insulating layer 404. N+ source regions 406 and P body regions 405 are formed adjacent to the gate electrodes 403. The gate electrode 403 and the shield electrode 403′ are made of doped poly-silicon layers. The shield electrode 403′ has lower doping concentration than the gate electrode 403 for reduction of reverse recovery charge. The resistance of the parasitic resistor between the shield electrode and the source metal is proportional to sheet resistance of the shield electrode.

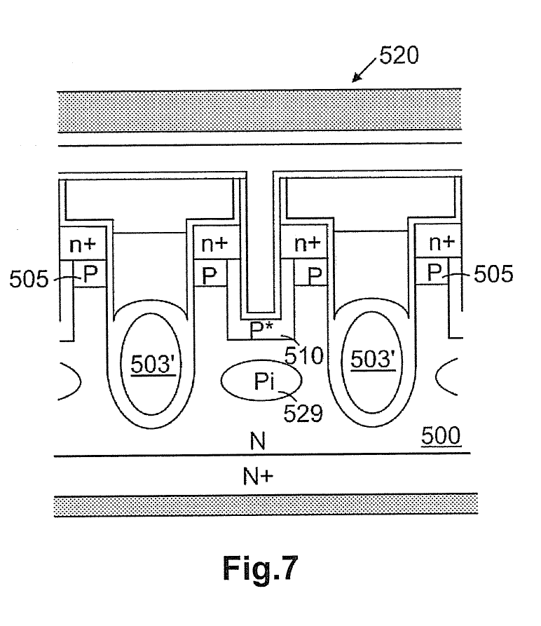

Please refer to FIG. 7 for another preferred N-channel trench MOSFET 520 with two type gate trenches for device shrinkage by forming self-aligned contact and super pinch-off regions for reduced on-resistance by forming a short channel according to the present invention, which has similar configuration to FIG. 6 except that, there is an additional single implanted P type pinch-off island Pi 529 in N epitaxial layer 500 underneath anti-PT P* region 510 and between two adjacent shield electrodes 503′ to form a third type pinch-off region between the shield electrodes 503′ and the single implanted P type pinch-off island Pi 529 for further Idsx reduction.

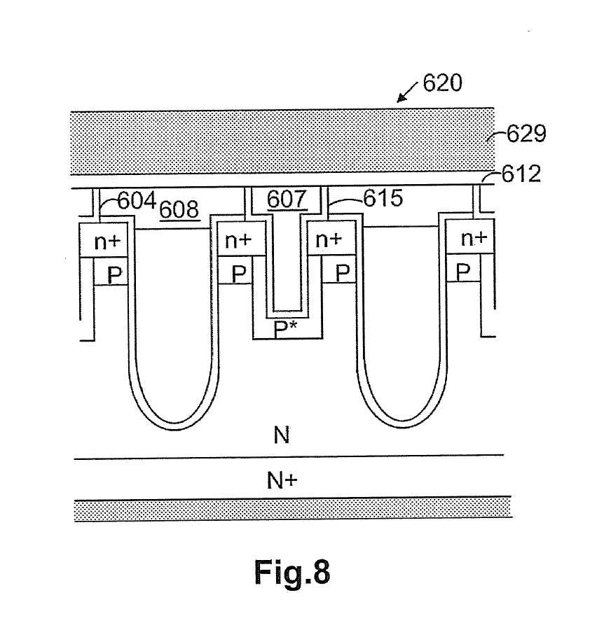

Please refer to FIG. 8 for another preferred N-channel trench MOSFET 620 with two type gate trenches and super pinch-off regions according to the present invention, which has similar configuration to FIG. 3A except that, tungsten metal 607 together with the padded barrier layer is etched back to be kept remain within source-body contact trench 615. Source metal 629 supported on a resistance-reduction layer 612 is formed covering top surface of the tungsten metal 607 and dielectric region 608 formed within first type gate trenches 604.

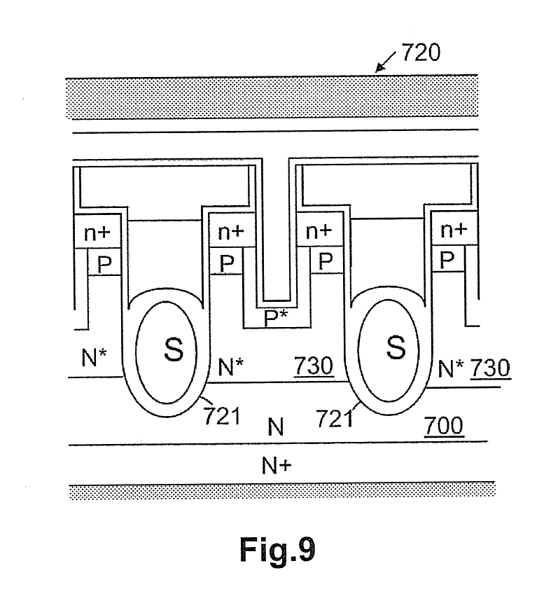

Please refer to FIG. 9 for another preferred N-channel trench MOSFET 720 with two type gate trenches for device shrinkage by forming self-aligned contact and super pinch-off regions for reduced on-resistance by forming a short channel according to the present invention, which has similar configuration to FIG. 6 except that an on-resistance reduction implanted N* region 730 is formed in upper portion of N epitaxial layer 700 and extending between two adjacent second type trenches 721, wherein the on-resistance reduction implanted N* region 730 has higher doping concentration than the N epitaxial layer 700 to further reduce Rds (resistance between the drain and the source) of the trench MOSFET 720 without degrading breakdown voltage with a thicker oxide surrounding bottom and sidewalls of the shield electrode.

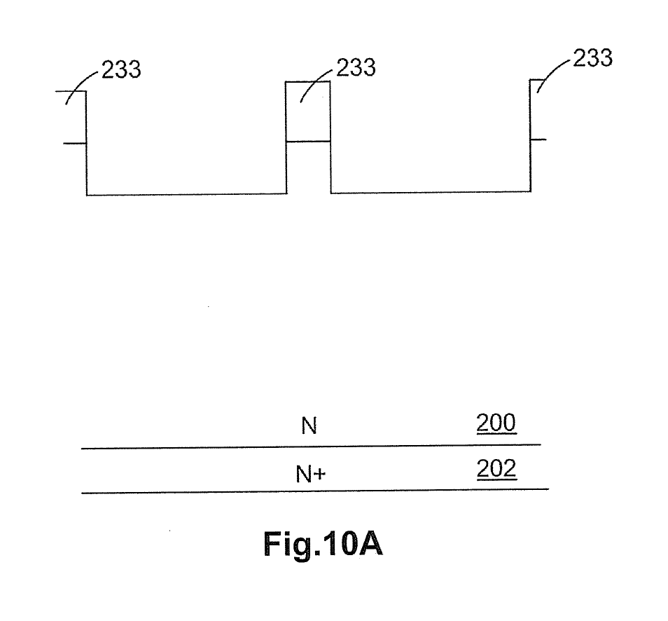

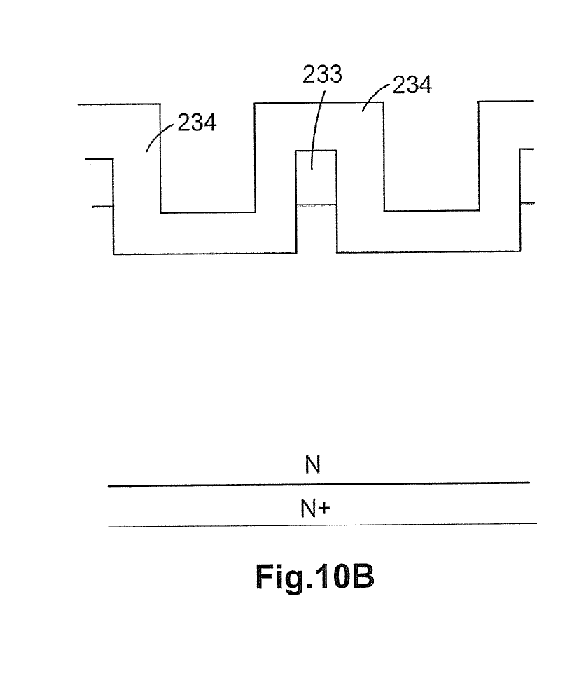

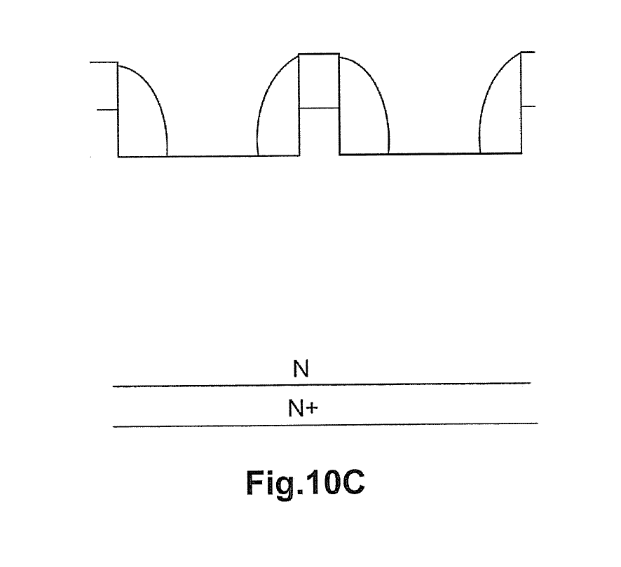

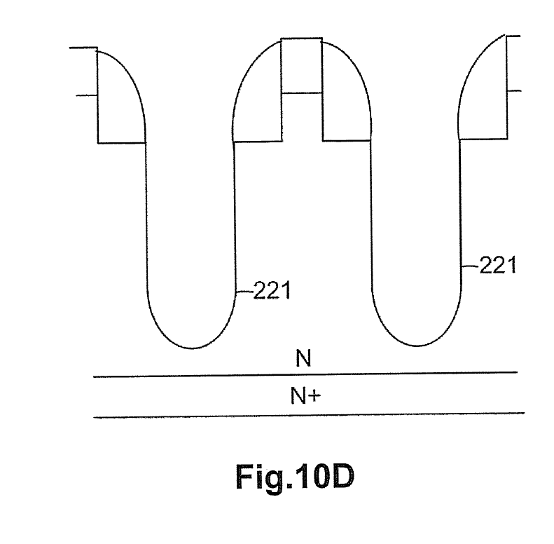

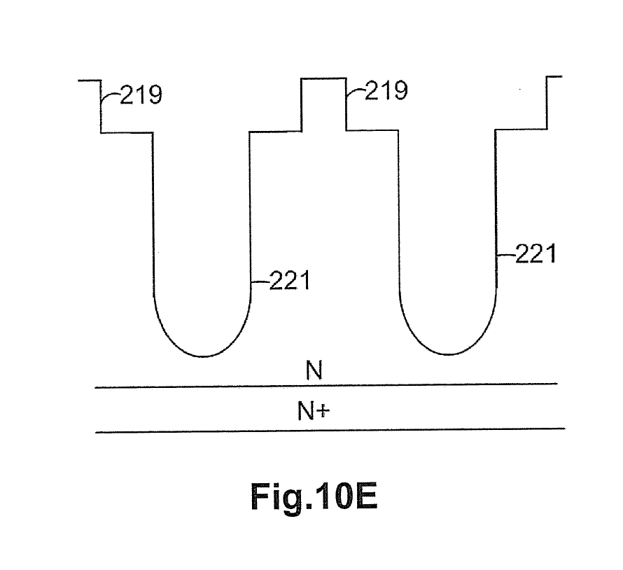

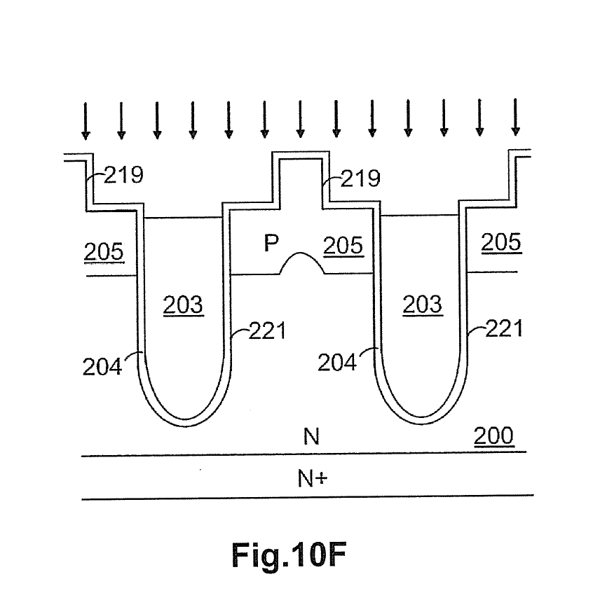

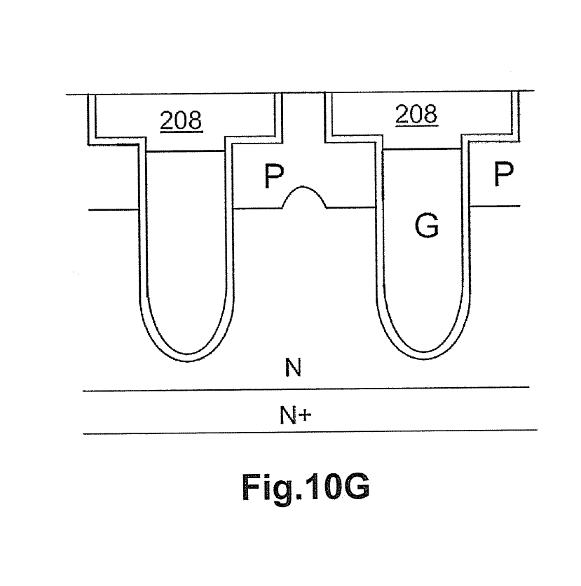

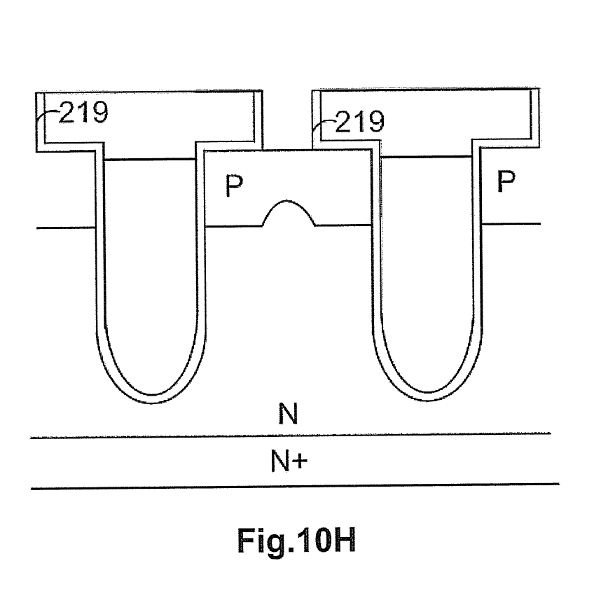

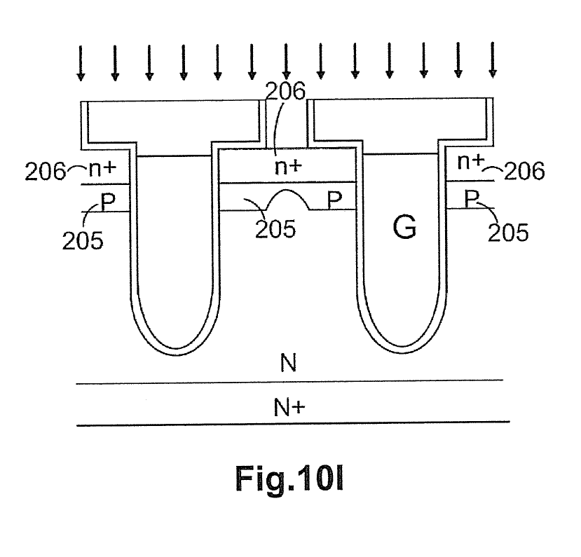

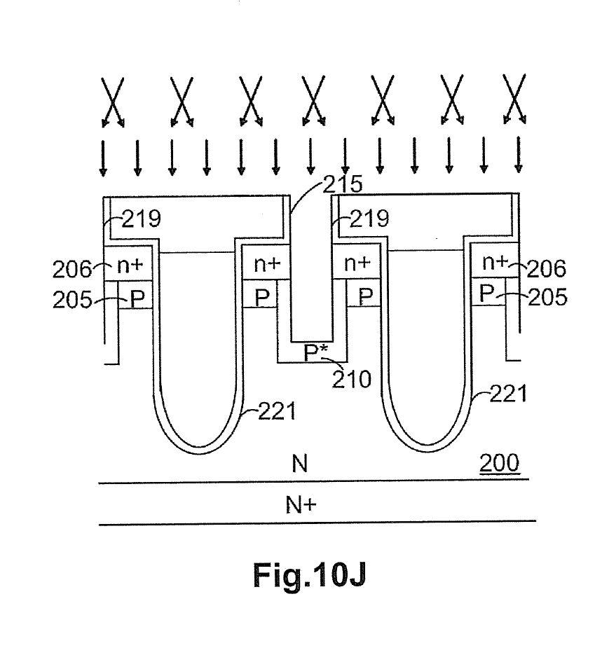

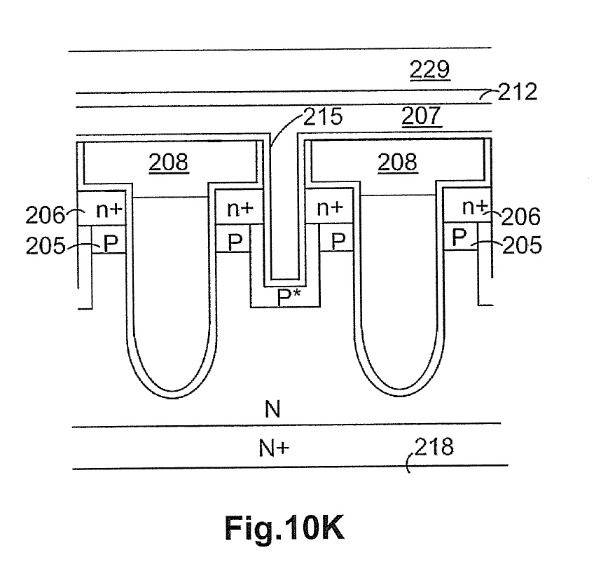

FIGS. 10A to 10K are a serial of exemplary steps that are performed to form the preferred N-channel trench MOSFET in FIG. 3A. In FIG. 10A, an N epitaxial layer 200 is grown on an N+ substrate 202. Then, a first oxide layer 233 is deposited onto top surface of the N epitaxial layer 200 as hard mask. Next, a trench mask (not shown) is applied onto the first oxide layer 233. After that, a dry oxide etching process and a dry silicon etching process is successively carried out to form a plurality of trenches which are extended to a certain depth in the N epitaxial layer 200.

In FIG. 10B, a second oxide layer 234 is deposited along inner surface of those trenches formed in FIG. 10A and along outer surface of the first oxide layer 233.

In FIG. 10C, a dry oxide etching process is carried out to form oxide sidewall spacer along sidewalls of those trenches formed in FIG. 10A.

In FIG. 10D, a dry silicon etching process is carried out along the oxide sidewall spacer formed in FIG. 10C to form a plurality second type gate trenches 221 symmetrically below those trenches formed in FIG. 10A with narrower trench width.

In FIG. 10E, the oxide sidewall spacer formed in FIG. 10C and the first oxide layer 233 deposited in FIG. 10A serving as hard mask are both removed away, and a sacrificial oxide layer (not shown) is formed and removed to eliminate the plasma damage introduced while etching the second type gate trenches 221. Meanwhile, a plurality of first type gate trenches are therefore formed symmetrically above the second type gate trenches 221 with greater trench width.

In FIG. 10F, a gate oxide layer 204 is formed along inner surface of the first type gate trenches 219 and the second type gate trenches 221, as well as along outer surface of the N epitaxial layer 200. After that, a doped poly-silicon layer 203 is deposited onto the gate oxide layer 204, and a portion of the doped poly-silicon layer 203 is removed away by successively doped poly-silicon CMP (Chemical Mechanical Polishing) process and doped poly-silicon etching process such that the left portion of the poly-silicon layer 203 is remained within the second type gate trenches 221 to serve as gate electrodes. Next, a step of Boron ion implantation is carried out without a mask to form a plurality of P body regions 205 between two adjacent second type gate trenches 221 with shallower depth in center portion of each P body region 205 after driving in.

In FIG. 10G, a BPSG (Boron Phosphorus Silicon Glass) layer 208 is deposited into the first type gate trenches 219 followed by a BPSG flow step to form dielectric region over the gate electrodes.

In FIG. 10H, a dry silicon etching process is carried out to remove portion of the N epitaxial layer away from the spaces between every two adjacent of the first type gate trenches 219.

In FIG. 10I, an N type dopant ion implantation is carried out without a mask to form n+ source regions 206 which extending in upper portion of the P body regions 205 after diffusion.

In FIG. 10J, a dry silicon etching process is carried out along sidewalls of the first type gate trenches 219 till penetrating through the n+ source regions 206 and the P body regions 205 and extending into the N epitaxial layer 200 between two adjacent of the second type gate trenches 221 to form a source-body contact trench 215. Therefore, the source-body contact trenches 215 are self-aligned to the first type gate trenches 219. Then, a BF2 ion implantation step with a dose ranging from 1 E12 to 1 E14 cm⁻² for formation of a soft recovery diode is carried out without a mask to form P* anti-punch through regions 210 surrounding bottom and sidewalls of the source-body contact trench 215 below the n+ source regions 206. The formation process of the P* anti-punch through regions 210 comprises angle ion implantation process and optional zero degree BF2 ion implantation process. Alternatively, the P* anti-punch regions can be heavily doped with a BF2 dose greater than 1 E14 cm−2 for further avalanche capability enhancement.

In FIG. 10K, a barrier layer of Ti/TiN or Co/TiN or Ta/TiN is deposited along inner surface of the source-body contact trench 215 and covering top surface of the BPSG layers 208. Then, a step of RTA (Rapid Thermal Annealing) process is carried out to form silicide. Next, onto the barrier layer, a tungsten metal is deposited filling into the source-body contact trenches 215 and over top surface of the BPSG layer 208. Then, onto the tungsten metal 207, an Al alloys metal 229 optionally padded by a resistance-reduction layer 212 of Ti or Ti/TiN is deposited to serve as source metal for contacting the n+ source regions 206 and the P body regions 205. Finally, on rear side of the N+ substrate 202, a back metal is deposited to serve as drain metal 218. Alternatively, the source metal can be Cu, Ni/Au, Ni/Ag, Ni/Au or Ni/Ag over Al alloys.

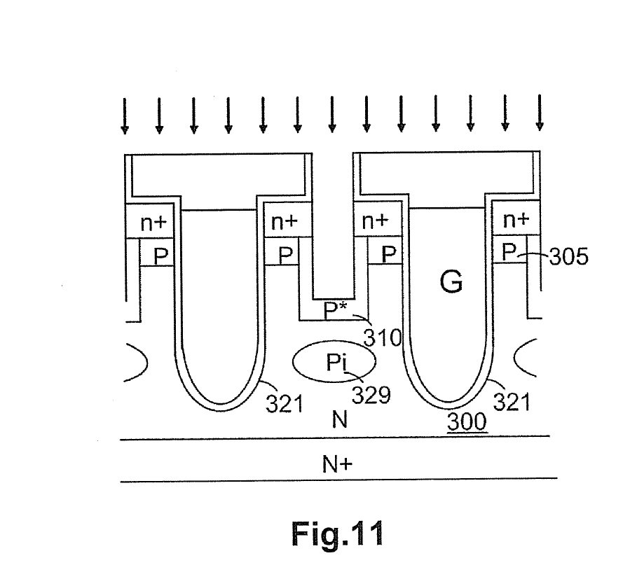

FIG. 11 is one of exemplary steps that are performed to form the preferred N-channel trench MOSFET in FIG. 5. The fabricating process of the trench MOSFET in FIG. 5 is similar to that of the trench MOSFET in FIG. 3A, except that, after the formation of P* anti-punch through region 310, another P type dopant ion implantation is carried out without a mask to form an additional single implanted P type pinch-off island Pi 329 in N epitaxial layer 300 underneath anti-PT P* region 310 and between two adjacent second type gate trenches 321 to form a third type pinch-off region between the second type gate trenches 321 and the single implanted P type pinch-off island Pi 329 for further Idsx reduction.

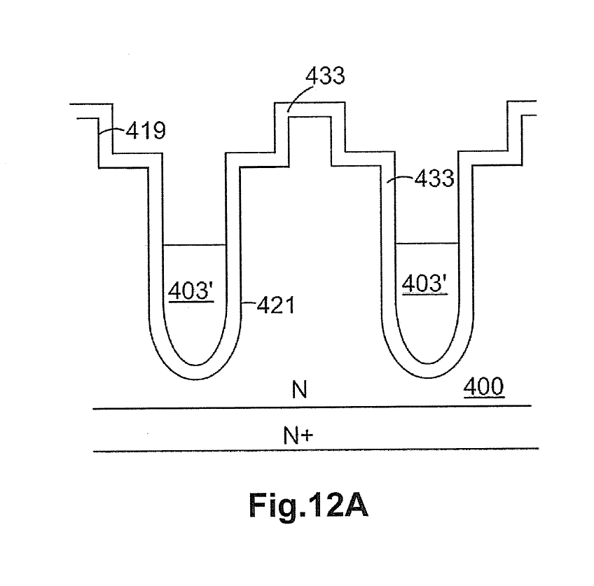

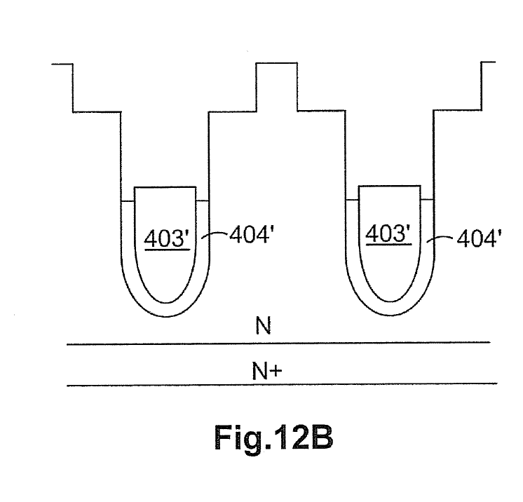

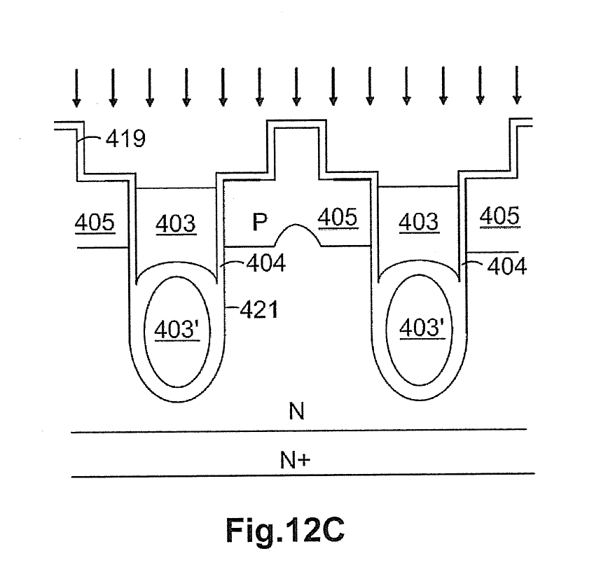

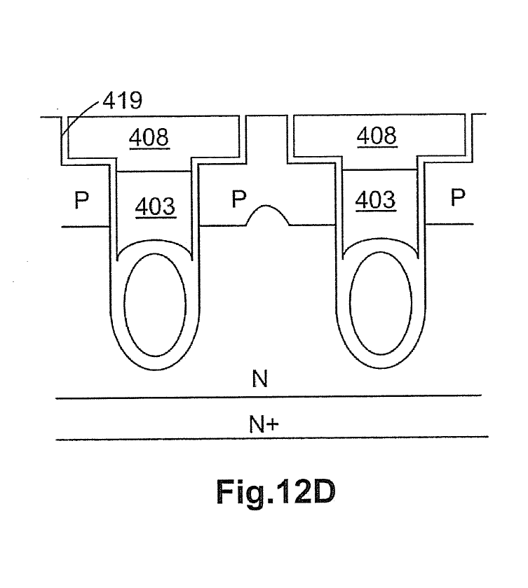

FIGS. 12A to 12D are a serial of exemplary steps that are performed to form the preferred N-channel trench MOSFET in FIG. 6. In FIG. 12A, after the formation of first type gate trenches 416 and second type gate trenches 421 in N epitaxial layer 400 (which are similar to those steps illustrated in FIGS. 10A to 10E), a sacrificial oxide layer 404′ is deposited along inner surface of the first type gate trenches 419 and the second type gate trenches 421, as well as along outer surface of the N epitaxial layer 400. Then, a first doped poly-silicon layer is deposited on to the sacrificial oxide layer 404′ and followed by a step of doped poly-silicon CMP. After that, a poly mask (not shown) is applied before performing a dry doped poly-silicon etching process to leave portion of the first doped poly-silicon within lower portion of the second type gate trenches 421 to serve as shield electrodes 403′.

In FIG. 12B, the sacrificial oxide layer 404′ is etched back to be partially removed away the portion above the shield electrodes 403′.

In FIG. 12C, a step of gate oxidation is performed to form gate oxide layer 404 covering the shield electrodes 403′ and covering sidewalls of the first type gate trenches 419 and sidewalls of the second type gate trenches 421 above the shield electrodes 403′. Then, after a second doped poly-silicon layer is deposited onto the gate oxide layer 404, a doped poly-silicon CMP process and a doped poly-silicon etching back process is successively carried out to form gate electrodes 403 within upper portion of the second type gate trenches 421. Next, a step of Boron ion implantation is carried out without a mask to form a plurality of P body regions 405 between two adjacent second type gate trenches 421 with shallower depth in center portion of each P body region 405 after driving in.

In FIG. 12D, a BPSG layer 408 is deposited into the first type gate trenches 419 followed by a BPSG flow step to form dielectric region over the gate electrodes 403.

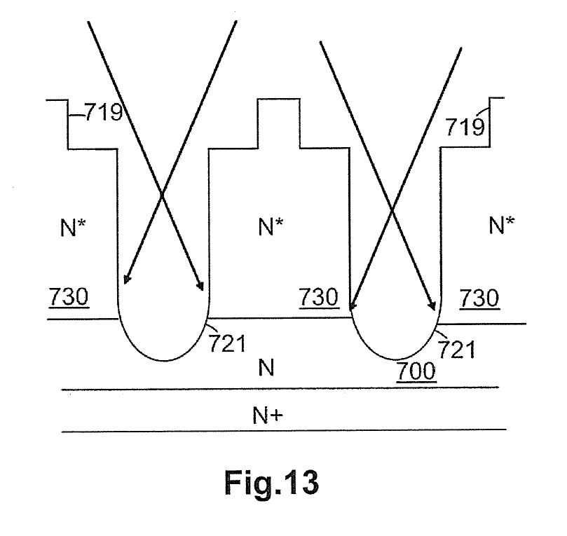

FIG. 13 is one of exemplary steps that are performed to form the preferred N-channel trench MOSFET in FIG. 9. The fabricating process of the trench MOSFET in FIG. 9 is similar to that of the trench MOSFET in FIG. 6, except that, after the formation of first type gate trenches 719 and second type gate trenches 721, an N type dopant angle ion implantation is carried out without a mask to form an on-resistance reduction implanted N* region 730 in upper portion of N epitaxial layer 700 and extending between two adjacent second type trenches 721, wherein the on-resistance reduction implanted N* region 730 has higher doping concentration than the N epitaxial layer 700 to further reduce Rds.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A power semiconductor device comprising:
a plurality of first type gate trenches extending into a silicon layer of a first conductivity type;
a plurality of second type gate trenches extending into said silicon layer and disposed below said first type gate trenches, each second type gate trench having narrower trench width than said first type gate trench, and each second type trench surrounded by source regions of said first conductivity type and body regions of a second conductivity type adjacent opposing sidewalls of each second type trench in upper portion of said silicon layer;
a gate electrode filled in said second type gate trenches;
a dielectric layer filled in said first type gate trenches symmetrically over said gate electrode;
a gate insulating layer insulating said gate electrode from adjacent body regions, source regions and silicon layer;
a plurality of source-body contact trenches formed between two adjacent of said first type gate trenches and penetrating through said source regions and said body regions and extending into said silicon layer between two adjacent of said second type gate trenches; and
an anti-punch through region of said second conductivity type surrounding sidewall and bottom of each said source-body contact trench below said source region.

2. The power semiconductor device of claim 1 wherein said second type gate trench symmetrically disposed below said first type gate trench.

3. The power semiconductor device of claim 1 wherein said gate electrode is doped poly-silicon layer.

4. The power semiconductor device of claim 1 further comprising a tungsten layer padded by a barrier layer filled into each source-body contact trench for contacting said sources region and said body regions along sidewalls of said source-body contact trenches, said tungsten layer electrically connected to a source metal.

5. The power semiconductor device of claim 4, wherein said tungsten layer is only filled within each source-body contact trench but not extended over on top surface of said dielectric layer filled in first type gate trenches.

6. The power semiconductor device of claim 4, wherein said tungsten layer is not only filled within each source-body contact trench but also further extended over top surface of said dielectric layer filled in said first type trenched gate.

7. The power semiconductor device of claim 1 further comprising an on-resistance reduction implanted region of said first conductivity type extending between two adjacent of said second type gate trenches below said body regions for further Rds reduction, said on-resistance reduction region having higher doping concentration than said silicon layer.

8. The power semiconductor device of claim 1 further comprising at least one implanted pinch-off island of said second conductivity type in said silicon layer underneath said anti-punch through region and between two adjacent of said gate electrodes for further Idsx reduction.

9. The power semiconductor device of claim 4, wherein said source metal is Al alloys or Cu layer.

10. The power semiconductor device of claim 4, wherein said source metal is Ni/Ag or Ni/Au layer.

11. The power semiconductor device of claim 4, wherein said source metal is composed of a Ni/Au or Ni/Ag over a Al alloys layer.

12. The power semiconductor device of claim 4 further comprises a resistance reduction layer such as Ti or Ti/TiN layer underneath said source metal.

13. The power semiconductor device of claim 1, wherein said source-body contact trenches are self-aligned to said first type gate trenches.

14. The power semiconductor device of claim 1, wherein said silicon layer is an epitaxial layer of said first conductivity type supported onto a substrate of said first conductivity type, wherein said epitaxial layer having lower doping concentration than said substrate.

15. The power semiconductor device of claim 1, wherein said dielectric layer is BPSG layer.

16. A power semiconductor device comprising:
a plurality of first type gate trenches extending into a silicon layer of a first conductivity type;
a plurality of second type gate trenches extending into said silicon layer, disposed below said first type gate trenches, each second type gate trench having narrower trench width than said first type gate trench, and each second type gate trench surrounded by source regions of said first conductivity type and body regions of a second conductivity type adjacent opposing sidewalls of each second type gate trench in upper portion of said silicon layer;
a gate electrode in said second type gate trenches over a shield electrode, wherein said gate electrode and said shield electrode insulated from each other by an inter-electrode insulation layer and from adjacent said body regions, said source regions and said silicon layer by gate insulating layers, wherein said source regions and said body regions being adjacent to said gate electrode;
said gate electrode connected to a gate metal and shielded electrode to a source metal;
a dielectric layer filled in said first type gate trenches;
a plurality of source-body contact trenches formed between two adjacent of said first type gate trenches and penetrating through said source regions and said body regions and extending into said silicon layer between two adjacent of said second type gate trenches; and
an anti-punch through region of said second conductivity type surrounding sidewall and bottom of each said source-body contact trench below said source region.

17. The power semiconductor device of claim 16 wherein said second type gate trench symmetrically disposed below said first type gate trench.

18. The power semiconductor device of claim 16 wherein said gate electrode and shield electrode are doped poly-silicon layers; and said shield electrode has lower doping concentration than said gate electrode.

19. The power semiconductor device of claim 18 further comprising a parasitic resistor disposed between said shield electrode and said source metal, said parasitic resistor has a resistance from 0.5 ohms to 200 ohms adjusted by sheet resistance of said shield electrode.

20. The power semiconductor device of claim 16 further comprising a tungsten layer padded by a barrier layer filled into each source-body contact trench for contacting said source regions and said body regions along sidewalls of said source-body contact trenches, said tungsten layer electrically connected to said source metal.

21. The power semiconductor device of claim 20, wherein said tungsten layer is only filled within each source-body contact trench but not extended over on top surface of said dielectric layer.

22. The power semiconductor device of claim 20, wherein said tungsten layer is not only filled within each source-body contact trench but also further extended over top surface of said silicon dielectric layer filled in said first type trenched gate

23. The power semiconductor device of claim 16 further comprising an on-resistance reduction implanted region of said first conductivity type extending between two adjacent of said second type gate trenches below said body regions for further Rds reduction, said on-resistance reduction region having higher doping concentration than said silicon layer.

24. The power semiconductor device of claim 16 further comprising at least one implanted pinch-off island of said second conductivity type in said silicon layer underneath said anti-punch through region and between two adjacent of said shield electrodes for further Idsx reduction.

25. The power semiconductor device of claim 16, wherein said gate insulating layers comprising a thicker oxide layer on bottom and sidewalls of said shield electrodes and a thinner oxide layer on sidewalls of said gate electrodes.

26. The power semiconductor device of claim 20, wherein said source metal is Al alloys or Cu layer.

27. The power semiconductor device of claim 20, wherein said source metal is Ni/Ag or Ni/Au layer.

28. The power semiconductor device of claim 20, wherein said source metal is composed of a Ni/Au or Ni/Ag over a Al alloys layer.

29. The power semiconductor device of claim 20 further comprises a resistance reduction layer such as Ti or Ti/TiN layer underneath said source metal.

30. The power semiconductor device of claim 16, wherein said source-body contact trenches are self-aligned to said first type gate trenches.

31. The power semiconductor device of claim 16, wherein said silicon layer is an epitaxial layer supported onto a substrate of said first conductivity type.

32. The power semiconductor device of claim 16, wherein said dielectric layer is BPSG layer.

33. A method for manufacturing a power semiconductor device comprising the steps of:
forming a plurality of first type gate trenches extending into a silicon layer;
forming a plurality of second type gate trenches in said silicon layer, symmetrically disposed below said first type gate trenches after forming said first type gate trenches, wherein said second type gate trenches having narrower trench width than said first type gate trenches;
forming body regions having opposite conductivity type to said silicon layer between two adjacent of said first type gate trenches and in upper portion of said silicon layer between two adjacent of said second type gate trenches;
forming dielectric layer within said first type gate trenches;
removing portion of said body regions from spaces between two adjacent of said first type gate trenches; then forming source regions having opposite conductivity type to said body regions in upper portion of said body regions;
forming a plurality of source-body contact trenches along sidewalls of said first type gate trenches and penetrating through said source regions and said body regions and extending into said silicon layer between two adjacent of said second type gate trenches, wherein said source-body contact trenches are self-aligned to said first type gate trenches; and
forming an anti-punch through region surrounding bottom and sidewall of each source-body contact trench below said source region.

34. The method of claim 33 further comprising the steps of:
forming a gate electrode within each second type gate trench onto a gate insulating layer after formation of the first type gate trenches and the second type gate trenches.

35. The method of claim 33 further comprising the steps of:
forming a gate electrode and a shield electrode made of doped poly-silicon within each second type gate trench onto gate insulating layers, wherein said gate electrode and said shield electrode insulated from each other, and said gate electrode has higher doping concentration than said shield electrode.

36. The method of claim 33 further comprising the steps of:
forming an on-resistance reduction implanted region having same conductivity type as said silicon layer after the formation of said first type gate trenches and said second type gate trenches, wherein said on-resistance reduction implanted region having higher doping concentration than said silicon layer and extending in upper portion of said silicon layer and between two adjacent of said second type gate trenches.

37. The method of claim 33 wherein said anti-punch through region is formed by BF2 ion implantation for N channel device, with a dose ranging from 5 E12 to 1 E14 cm⁻² for formation of a soft recovery diode.

38. The method of claim 33 wherein said anti-punch through region is formed by BF2 ion implantation for N channel device, with a dose greater than 1 E14 cm⁻² for avalanche capability enhancement.

39. The method of claim 33 further comprising the steps of:
forming a single pinch-off island having same conductivity type as said body region underneath said anti-punch region after the formation of said anti-punch through region between two adjacent of said second type gate trenches.
